(19) United States
(12) Patent Application Publication
(10) Pub. No.: US 2023/0290892 A1
(43) Pub. Date: Sep. 14, 2023

(54) RESONANT TUNNELING DIODES AND MANUFACTURING METHODS THEREOF

(71) Applicant: ENKRIS SEMICONDUCTOR, INC., Suzhou, Jiangsu (CN)

(72) Inventor: Kai Cheng, Shuzhou, Jiangsu (CN)

(73) Assignee: ENKRIS SEMICONDUCTOR, INC., Suzhou, Jiangsu (CN)

(21) Appl. No.: 17/788,967

(22) PCT Filed: Mar. 5, 2021
(86) PCT No.: PCT/CN2021/079264

§ 371 Date: Jun. 24, 2022

(51) Int. Cl. H01L 29/88; H01L 29/20; H01L 29/66

(52) U.S. Cl. CPC H01L 29/882; H01L 29/2003; H01L 29/66219

(57) ABSTRACT

The present disclosure provides a resonant tunneling diode and a manufacturing method thereof. The resonant tunneling diode includes: a first barrier layer; a second barrier layer; and a potential well layer between the first barrier layer and the second barrier layer, a material of the first barrier layer being AlₓIn_{y}N_{1-x-y}, 1>x>0, 1>y>0, and/or a material of the second barrier layer being AlₘInₙN₁₋ₘ₋ₙ, 1>m>0, 1>n>0, and a material of the well layer including a gallium element.

### CROSS-REFERENCE TO RELATED APPLICATIONS

This application is a U.S. National Phase of PCT Application No. PCT/CN2021/079264 (filed 5 Mar. 2021), the entire contents of which are incorporated herein by reference.

### TECHNICAL FIELD

The present disclosure relates to the field of semiconductor technology, and more particularly to resonant tunneling diodes and manufacturing methods thereof.

### BACKGROUND

Terahertz technology, as a new science and technology, has important application prospects in security detection, material identification, secure communication, space exploration, high-precision radar, tissue biopsy, transient spectrum research and so on. A resonant tunneling diode, as a dual-terminal device, can produce negative differential resistance by using resonant tunneling phenomenon, which is configured to prepare terahertz radiation source, resulting in a wide range of concerns.

At present, a mature resonant tunneling diode (RTD) is mainly a GaAs-based material, due to inherent performance limitations of GaAs-based materials, a power of RTD merely reaches an order of micro watts. GaN-based resonant tunneling diodes have advantages of group III nitride semiconductor materials, such as, high electron rate, high breakdown field strength, large band gap adjustable range and radiation resistance. With this configuration, it is expected to realize terahertz high-power emission at room temperature.

However, at present, nitride-based resonant tunneling diodes face problems of a poor device stability and a low peak-to-valley current ratio, which greatly limits its practical application.

### SUMMARY

An object of the present disclosure is to provide a resonant tunneling diode and a manufacturing method thereof, so as to improve a device stability and a peak-to-valley current ratio.

To achieve the above object, a first aspect of the present disclosure provides a resonant tunneling diode, including:

a first barrier layer; a second barrier layer; and a potential well layer between the first barrier layer and the second barrier layer, where a material of the first barrier layer is AlₓIn_{y}N_{1-x-y}, 1>x>0, 1>y>0, and/or a material of the second barrier layer is AlₘInₙN₁₋ₘ₋ₙ, 1>m>0, 1>n>0, and a material of the potential well layer includes a gallium element.

In some embodiments, the material of the potential well layer include at least one of InGaN, GaN, or AlInGaN.

In some embodiments, the material of the first barrier layer is AlₓIn_{y}N_{1-x-y}, y≤45%, and/or the material of the second barrier layer is AlₘInₙN₁₋ₘ₋ₙ, n≤45%.

In some embodiments, the material of the first barrier layer is AlₓIn_{y}N_{1-x-y}, y≤30%; the material of the second barrier layer is AlₘInₙN₁₋ₘ₋ₙ, n≤30%.

In some embodiments, a first isolation layer is disposed between the first barrier layer and the potential well layer; and/or a second isolation layer is disposed between the second barrier layer and the potential well layer.

In some embodiments, a material of the first isolation layer and/or a material of the second isolation layer includes AlN.

In some embodiments, a thickness of the first isolation layer ranges from 0.1 nm to 2 nm; and/or a thickness of the second isolation layer ranges from 0.1 nm to 2 nm.

In some embodiments, the resonant tunneling diode further includes a collector electrode and an emitter, the collector electrode close to the first barrier layer, the emitter close the second barrier layer; a third isolation layer between the collector electrode and the first barrier layer; and/or a fourth isolation layer between the emitter and the second barrier layer.

In some embodiments, a material of the collector electrode and a material of the emitter include a GaN-based material.

In some embodiments, a material of the third isolation layer and/or a material of a fourth isolation layer include AlN.

A second aspect of the present disclosure provides a method of manufacturing a resonant tunneling diode, including:

epitaxially growing a first barrier layer, a potential well layer, and a second barrier layer; where a material of the first barrier layer is AlₓIn_{y}N_{1-x-y}, 1>x>0, 1>y>0, and/or a material of the second barrier layer is AlₘInₙN₁₋ₘ₋ₙ, 1>m>0, 1>n>0, and a material of the potential well layer including a gallium element.

In some embodiments, the material of the potential well layer include at least one of InGaN, GaN, or AlInGaN.

In some embodiments, the material of the first barrier layer is AlₓIn_{y}N_{1-x-y}, y≤30%; and/or the material of the second barrier layer is AlₘInₙN₁₋ₘ₋ₙ, n≤30%.

In some embodiments, if the material of the first barrier layer is AlₓIn_{y}N_{1-x-y}, a temperature of epitaxially growing the first barrier layer ranges from 600° C. to 900° C.; and if the material of the second barrier layer is AlₘInₙN₁₋ₘ₋ₙ, a temperature of epitaxially growing the second barrier layer ranges from 600° C. to 900° C.

In some embodiments, the method of manufacturing the resonant tunneling diode further includes: before epitaxially growing the potential well layer, epitaxially growing a first isolation layer on the first barrier layer; and/or before epitaxially growing the second barrier layer, epitaxially growing a second isolation layer on the potential well layer.

In some embodiments, epitaxially growing a collector electrode on a side of the first barrier layer away from the potential well layer; or before epitaxially growing the first barrier layer, epitaxially growing the collector electrode; and epitaxially growing an emitter on a side of the second barrier layer away from the potential well layer.

In some embodiments, the method of manufacturing the resonant tunneling diode further includes: before epitaxially growing the collector electrode on the side of the first barrier layer away from the potential well layer, epitaxially growing a third isolation layer on the side of the first barrier layer away from the potential well layer; or after epitaxially growing the collector electrode and before epitaxially growing the first barrier layer, epitaxially growing the third isolation layer;

and/or before epitaxially growing the emitter on the side of the second barrier layer away from the potential well layer, epitaxially growing a fourth isolation layer on the side of the second barrier layer away from the potential well layer.

In some embodiments, a material of the collector electrode and a material of the emitter include a GaN-based material.

In some embodiments, a material of the first isolation layer and/or a material of the second isolation layer includes AlN.

In some embodiments, a thickness of the first isolation layer ranges from 0.1 nm to 2 nm; and/or a thickness of the second isolation layer ranges from 0.1 nm to 2 nm.

Compared with the related art, the present disclosure has the following beneficial effects:

In the present disclosure, AlN-based material including indium element is used as the first barrier layer and/or the second barrier layer, and thus temperatures of growing the first barrier layer and the second barrier layer are correspondingly decreased, thereby avoiding a high temperature process. The absence of the high temperature process can prevent gallium atoms in the potential well layer from diffusing to the first barrier layer and the second barrier layer due to a high temperature, ensuring that compositions of the first barrier layer and the second barrier layer are uniform, preventing an effective thickness from thinning, thereby improving a device stability and a peak-to-valley current ratio.

Meanwhile, the first isolation layer and the second isolation layer can prevent gallium atoms in the potential well layer from diffusing to the first barrier layer and the second barrier layer, ensuring that compositions of the first barrier layer and the second barrier layer are uniform, preventing an effective thickness from thinning, thereby improving a device stability and a peak-to-valley current ratio.

### BRIEF DESCRIPTION OF THE DRAWINGS

FIG. 1 is a flowchart of a method of manufacturing a resonant tunneling diode according to a first embodiment of the present disclosure;

FIG. 2 is a schematic view illustrating an intermediate structure corresponding to a process of FIG. 1;

FIG. 3 is a cross-sectional schematic view of a resonant tunneling diode according to a first embodiment of the present disclosure;

FIG. 4 is a flowchart of a method of manufacturing a resonant tunneling diode according to a second embodiment of the present disclosure;

FIG. 5 is a cross-sectional schematic view of a resonant tunneling diode according to a third embodiment of the present disclosure;

FIG. 6 is a cross-sectional schematic view of a resonant tunneling diode according to a fourth embodiment of the present disclosure;

FIG. 7 is a cross-sectional schematic view of a resonant tunneling diode according to a fifth embodiment of the present disclosure;

FIG. 8 is a cross-sectional schematic view of a resonant tunneling diode according to a sixth embodiment of the present disclosure; and

FIG. 9 is a cross-sectional schematic view of a resonant tunneling diode according to a seventh embodiment of the present disclosure.

To facilitate the understanding of the present disclosure, all reference numerals appearing in the present disclosure are listed below:

| | |
|---|---|
| resonant tunneling diodes 1, 2, 3, 4, 5, 6 | substrate 10; |
| first barrier layer 11 | second barrier layer 12 |
| potential well layer 13 | first isolation layer 14 |
| second isolation layer 15 | third isolation layer 16 |
| fourth isolation layer 17 | collector electrode 20 |
| emitter electrode 30 | |

### DETAILED DESCRIPTION OF THE EMBODIMENTS

To make the above objects, features and advantages of the present disclosure more apparent and understandable, embodiments of the present disclosure will be described in detail below with reference to accompanying drawings.

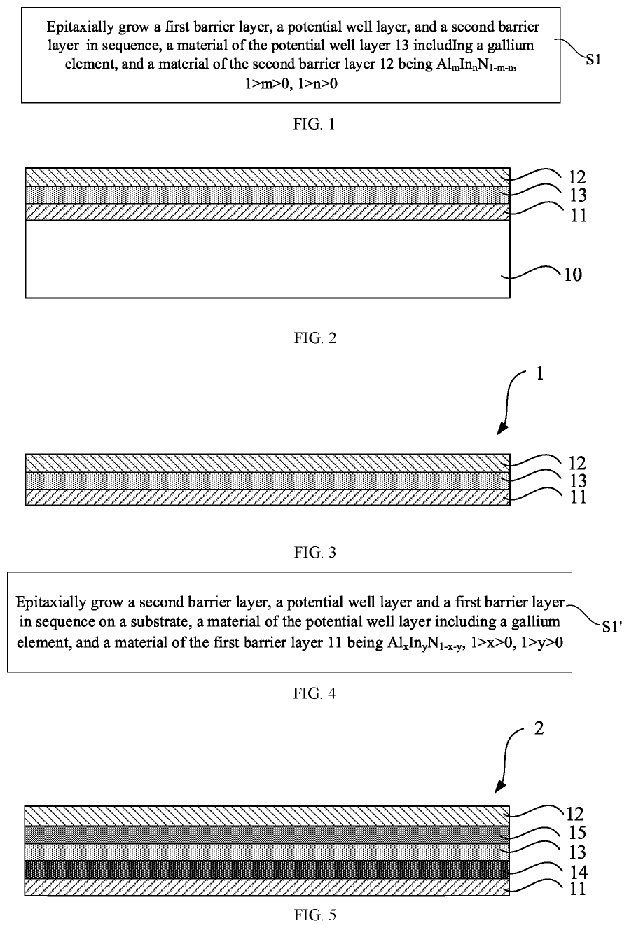

FIG. 1 is a flowchart of a method of manufacturing a resonant tunneling diode according to a first embodiment of the present disclosure; FIG. 2 is a schematic view illustrating an intermediate structure corresponding to a process of FIG. 1. FIG. 3 is a cross-sectional schematic view of a resonant tunneling diode according to a first embodiment of the present disclosure.

First, referring to step S1 in FIG. 1 and FIG. 2, a first barrier layer 11, a potential well layer 13, and a second barrier layer 12 are epitaxially grown in sequence, a material of the potential well layer 13 includes a gallium (Ga) element, and a material of the second barrier layer 12 is AlₘInₙN₁₋ₘ₋ₙ, 1>m>0, 1>n>0.

In this embodiment, the first barrier layer 11 can be epitaxially grown on the substrate 10.

A material of the substrate 10 can include at least one of sapphire, silicon carbide, silicon, or Silicon-On-Insulator (SOI) substrate; or at least one of sapphire, silicon carbide, silicon, or SOI substrate, and the group III nitride material; which is not limited in this embodiment.

The epitaxial growth processes of the first barrier layer 11, potential well layer 13 and the second barrier layer 12 can include: atomic layer deposition (ALD), chemical vapor deposition (CVD), molecular beam epitaxy (MBE), plasma enhanced chemical vapor deposition (PECVD), low pressure chemical vapor deposition (LPCVD), or metal-organic chemical vapor deposition (MOCVD), or a combination thereof.

In some embodiments, the material of the first barrier layer 11 includes AlGaN, if an MOCVD epitaxial growth method is adopted, a temperature of epitaxially growing the first barrier layer 11 ranges from 900° C. to 1300° C.

In this embodiment, it is noted that a chemical element represents a certain material, but molar ratios of respective chemical elements in a material are not limited. For example, an AlGaN material includes aluminum, gallium and nitrogen elements, but respective molar ratios of the three elements are not limited.

A band gap width of the potential well layer 13 is less than a band gap width of the first barrier layer 11.

The material of the potential well layer 13 includes GaN, a band gap width of the potential well layer 13 is 3.4 eV. If an MOCVD epitaxial growth method is adopted, a temperature of epitaxially growing the potential well layer 13 ranges from 800° C. to 1200° C.

The material of the second barrier layer 12 can be AlₘInₙN₁₋ₘ₋ₙ, m is a percentage of a mass for an aluminum element to a sum of masses for the aluminum element, an indium element and a nitrogen element, and n is a percentage of a mass for the indium element to a sum of masses for the aluminum element, the indium element and the nitrogen element. The higher a temperature of epitaxially growing the second barrier layer 12 is, the smaller the n is; the lower a temperature of epitaxially growing the second barrier layer 12 is, the greater the n is. The lower the temperature of epitaxially growing the second barrier layer 12 is, the more it can avoid a diffusion of gallium atoms in the potential well layer 13 to the first barrier layer 11 and the second barrier layer 12, respectively.

A band gap width of the second barrier layer 12 is greater than a band gap width of the potential well layer 13.

A band gap width of AlN is 6.2 eV, the higher an amount of an indium element in an AlInN material is, the smaller a band gap width of the AlInN material is. If n≤45%, the second barrier layer 12 and the potential well layer 13 which is made of a GaN material can form a quantum well with a high tunneling efficiency. If an MOCVD epitaxial growth method is adopted and if n≤45%, a temperature of epitaxially growing the second barrier layer 12 ranges from 600° C. to 900° C.; if 30%<n≤45%, the temperature of epitaxially growing the second barrier layer 12 ranges from 600° C. to 800° C.; and if n≤30%, the temperature of epitaxially growing the second barrier layer 12 ranges from 700° C. to 900° C.

However, the lower the temperature of epitaxially growing the second barrier layer 12 is, the more lattice defects are. Thus, in some embodiments, n≤30%.

In other embodiments, the material of the potential well layer 13 includes InGaN or AlInGaN, and a band gap width of InGaN is between 0.7 eV to 3.4 eV. A band gap width of AlInGaN is between 0.7 eV to 6.2 eV. The material of the second barrier layer 12 is AlₘInₙN₁₋ₘ₋ₙ, n≤45%, the second barrier layer 12 and the potential well layer 13 which is made of an InGaN material can form a quantum well with a higher tunneling efficiency. In some embodiments, n≤30%.

Using an AlN-based material including an indium element as the second barrier layer 12 can reduce a temperature of growing the second barrier layer 12, thereby avoiding a high temperature process, and avoiding a diffusion of gallium atoms in the potential well layer 13 to the first barrier layer 11 and the second barrier layer 12 respectively due to the high temperature, ensuring that compositions of the first barrier layer 11 and the second barrier layer 12 are uniform, and preventing an effective thickness from thinning, and thereby improving device stability and a peak-to-valley current ratio.

Thereafter, referring to FIG. 3, the substrate 10 is removed.

The substrate 10 can be removed by laser stripping or chemical etching.

In some embodiments, the substrate 10 can be not removed. In other words, the substrate 10 remains in the resonant tunneling diode 1.

Referring to FIG. 3, the resonant tunneling diode 1 according to the first embodiment of the present disclosure includes:

a first barrier layer 11; a second barrier layer 12; and a potential well layer 13 between the first barrier layer 11 and the second barrier layer 12, a material of the first barrier layer 11 including AlGaN, a material of the potential well layer 13 including a gallium (Ga) element, and a material of the second barrier layer 12 being AlₘInₙN₁₋ₘ₋ₙ, 1>m>0, 1>n>0.

The first barrier layer 11, the potential well layer 13, and the second barrier layer 12 form a dual barrier quantum well structure. A band gap width of the potential well layer 13 is less than a band gap width of the first barrier layer 11 and a band gap width of the second barrier layer 12. In some embodiments, the material of the potential well layer 13 includes GaN. The material of the second barrier layer 12 is AlₘInₙN₁₋ₘ₋ₙ, n≤45%, the second barrier layer 12 and the well layer 13 which is made of a GaN material can form a quantum well with a higher tunneling efficiency. In some embodiments, n≤30%.

In other embodiments, the material of the well layer 13 includes InGaN or AlInGaN. The material of the second barrier layer 12 is AlₘInₙN₁₋ₘ₋ₙ, n≤45%, the second barrier layer 12 and the potential well layer 13 which is made of an InGaN material can form a quantum well with a higher tunneling efficiency. In some embodiments, n≤30%.

FIG. 4 is a flowchart of a method of manufacturing a resonant tunneling diode according to a second embodiment of the present disclosure. Referring to FIG. 4, the resonant tunneling diode and the manufacturing method thereof in the second embodiment are substantially the same as the resonant tunneling diode 1 and the manufacturing method thereof in the first embodiment, except that, at step S1′, a second barrier layer 12, a potential well layer 13 and a first barrier layer 11 are epitaxially grown in sequence on the substrate 10, a material of the potential well layer 13 includes a gallium element, and a material of the first barrier layer 11 is AlₓIn_{y}N_{1-x-y}, 1>x>0, 1>y>0.

A material of the second barrier layer 12 can include AlGaN. The material of the potential well layer 13 can include at least one of InGaN, GaN, or AlInGaN.

The material of the first barrier layer 11 is AlₓIn_{y}N_{1-x-y}, x is a percentage of a mass for an aluminum element to a sum of masses for the aluminum element, an indium element and a nitrogen element, and y is a percentage of a mass for the indium element to a sum of masses for the aluminum element, the indium element and the nitrogen element. The higher a temperature of epitaxially growing the first barrier layer 11 is, the smaller the y is; the lower the temperature of epitaxially growing the first barrier layer 11 is, the greater the y is. The lower the temperature of epitaxially growing the first barrier layer 11 is, the more it can avoid a diffusion of gallium atoms in the potential well layer 13 to the first barrier layer 11 and the second barrier layer 12, respectively.

If y≤45%, the first barrier layer 11 and the potential well layer 13 which is made of a GaN material can form a quantum well with a high tunneling efficiency. If an MOCVD epitaxial growth method is adopted and if y≤45%, the temperature of epitaxially growing the first barrier layer 11 ranges from 600° C. to 900° C.; if 30%<y<45%, the temperature of epitaxially growing the first barrier layer 11 ranges from 600° C. to 800° C.; and if y≤30%, the temperature of epitaxially growing the first barrier layer 11 ranges from 700° C. to 900° C. However, the lower the temperature of epitaxially growing the first barrier layer 11 is, the more lattice defects are. Thus, in some embodiments, y≤30%.

Using an indium-including AlN-based material as the first barrier layer 11 can reduce the temperature of growing the first barrier layer 11, so as to avoid a high temperature process, and avoid a diffusion of gallium atoms in the potential well layer 13 to the first barrier layer 11 and the second barrier layer 12 respectively due to the high temperature, so as to ensure that compositions of the first barrier layer 11 and the second barrier layer 12 are uniform, and prevent an effective thickness from thinning, and thereby a device stability and a peak-to-valley current ratio is improved.

In the resonant tunneling diode in the second embodiment of the present disclosure, the material of the first barrier layer 11 is AlₓIn_{y}N_{1-x-y}, 1>x>0, 1>y>0.

In some embodiments, the material of the potential well layer 13 includes GaN. The material of the first barrier layer 11 is AlₓIn_{y}N_{1-x-y}, y≤45%, the first barrier layer 11 and the well layer 13 which is made of a GaN material can form a quantum well with a higher tunneling efficiency. In some embodiments, y≤30%.

In other embodiments, the material of the well layer 13 includes InGaN or AlInGaN. The material of the first barrier layer 11 is AlₓIn_{y}N_{1-x-y}, y≤45%, the first barrier layer 11 and the well layer 13 which is made of an InGaN material can form a quantum well with a higher tunneling efficiency. In some embodiments, y≤30%.

In some embodiments, the material of the second barrier layer 12, which is epitaxially grown on the substrate 10, can be AlₘInₙN₁₋ₘ₋ₙ, 1>m>0, 1>n>0; or the material of the first barrier layer 11, which is epitaxially grown on the substrate 10, is AlₓIn_{y}N_{1-x-y}, 1>x>0, 1>y>0.

FIG. 5 is a cross-sectional schematic view of a resonant tunneling diode according to a third embodiment of the present disclosure;

Referring to FIG. 5, a resonant tunneling diode 2 in the third embodiment is substantially the same as the resonant tunneling diode 1 in the first embodiment and the second embodiment, except that, a first isolation layer 14 is disposed between the first barrier layer 11 and the potential well layer 13, a second isolation layer 15 is disposed between the second barrier layer 12 and the potential well layer 13.

The arrangement of the first isolation layer 14 can prevent gallium atoms in the potential well layer 13 from diffusing to the first barrier layer 11, ensuring that compositions of the first barrier layer 11 are uniform, preventing an effective thickness from thinning, thereby improving a device stability and a peak-to-valley current ratio of the resonant tunneling diode 1. A material of the first isolation layer 14 can include AlN.

A thickness of the first isolation layer 14 can range from 0.1 nm to 2 nm.

The arrangement of the second isolation layer 15 can prevent gallium atoms in the potential well layer 13 from diffusing to the second barrier layer 12, ensuring that compositions of the second barrier layer 12 are uniform, preventing an effective thickness from thinning, thereby improving a device stability and a peak-to-valley current ratio of the resonant tunneling diode 1. A material of the second isolation layer 15 can include AlN.

A thickness of the second isolation layer 15 can range from 0.1 nm to 2 nm.

Correspondingly, a method of manufacturing the resonant tunneling diode 2 in the third embodiment is substantially the same as the method of manufacturing the resonant tunneling diode 1 in the first embodiment and the second embodiment, except that, before the potential well layer 13 is epitaxially grown, a first isolation layer 14 is epitaxially grown on the first barrier layer 11, before the second barrier layer 12 is epitaxially grown, a second isolation layer 15 is epitaxially grown on the potential well layer 13.

The epitaxial growth processes of the first isolation layer 14 and the second barrier layer 15 can refer to the epitaxial growth processes of the first barrier layer 11, the potential well layer 13, and the second barrier layer 12.

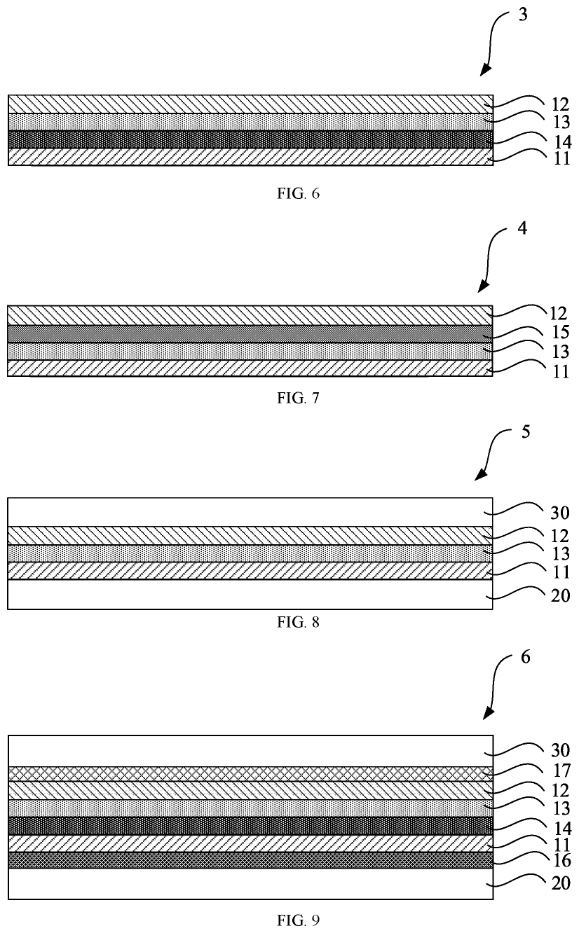

FIG. 6 is a cross-sectional schematic view of a resonant tunneling diode according to a fourth embodiment of the present disclosure;

Referring to FIG. 6, a resonant tunneling diode 3 and a manufacturing method thereof in the fourth embodiment are substantially the same as the resonant tunneling diode 2 and the manufacturing method thereof in the third embodiment, except that the second isolation layer 15 and a step of manufacturing the second isolation layer 15 are omitted.

FIG. 7 is a cross-sectional schematic view of a resonant tunneling diode according to a fifth embodiment of the present disclosure.

Referring to FIG. 7, a resonant tunneling diode 4 and a manufacturing method thereof in the fifth embodiment are substantially the same as the resonant tunneling diode 2 and the manufacturing method thereof in the third embodiment, except that the first isolation layer 14 and a step of manufacturing the first isolation layer 14 are omitted.

FIG. 8 is a cross-sectional schematic view of a resonant tunneling diode according to a sixth embodiment of the present disclosure.

Referring to FIG. 8, a resonant tunneling diode 5 in the sixth embodiment is substantially the same as the resonant tunneling diode 1 to the resonant tunneling diode 4 in the first embodiment to the fifth embodiment, except that a collector electrode 20 and an emitter electrode 30 are included, the collector electrode 20 is close to the first barrier layer 11, the emitter electrode 30 is close to the second barrier layer 12.

A material of the collector electrode 20 and a material of the emitter electrode 30 both include a group III nitride, for example, a GaN-based material, and more particularly, GaN.

Correspondingly, a manufacturing method in the present embodiment is substantially the same as the manufacturing methods in the previous embodiments, except that step S1 is followed by step S2, the collector electrode 20 is epitaxially grown on a side of the first barrier layer 11 away from the potential well layer 13, the emitter electrode 30 is epitaxially grown on a side of the second barrier layer 12 away from the potential well layer 13.

A material of the collector electrode 20 and a material of the emitter electrode 30 both include a group III nitride.

A difference between the manufacturing method in the present embodiment and the manufacturing method in the previous embodiment is that at step S1: before the first barrier layer 11 is epitaxially grown, the collector electrode 20 is epitaxially grown on the substrate 10; and/or before the substrate 10 is removed, the emitter electrode 30 is epitaxially grown on the second barrier layer 12.

The epitaxial growth processes of the collector electrode 20 and the emitter electrode 30 can refer to the epitaxial growth processes of the first barrier layer 11, the potential well layer 13, and the second barrier layer 12.

FIG. 9 is a cross-sectional schematic view of a resonant tunneling diode according to a seventh embodiment of the present disclosure.

Referring to FIG. 9, the resonant tunneling diode 6 in the seventh embodiment is substantially the same as the resonant tunneling diode 5 in the sixth embodiment, except that a third isolation layer 16 is disposed between the collector electrode 20 and the first barrier layer 11, and a fourth isolation layer 17 is disposed between the emitter electrode 30 and the second barrier layer 12.

The third isolation layer 16 can prevent gallium atoms in the collector electrode 20 from diffusing to the first barrier layer 11. The fourth isolation layer 17 can prevent gallium atoms in the emitter electrode 30 from diffusing to the second barrier layer 12.

A material of the third isolation layer 16 and a material of the fourth isolation layer 17 both can include AlN.

A thickness of the third isolation layer 16 can range from 0.1 nm to 2 nm. A thickness of the fourth isolation layer 17 can range from 0.1 nm to 2 nm.

In some embodiments, any one of the third isolation layer 16 and the fourth isolation layer 17 can be disposed.

Correspondingly, the manufacturing method in the present embodiment is substantially the same as the manufacturing method in the previous embodiment, except that at step S1: before the collector electrode 20 is epitaxially grown on a side of the first barrier layer 11 away from the potential well layer 13, the third isolation layer 16 is epitaxially grown on the side of the first barrier layer 11 away from the potential well layer 13; or after the collector electrode 20 is epitaxially grown on the substrate 10 and before the first barrier layer 11 is epitaxially grown, the third isolation layer 16 is epitaxially grown;

and/or at step S1: before the emitter electrode 30 is epitaxially grown on a side of the second barrier layer 12 away from the potential well layer 13, the fourth isolation layer 17 is epitaxially grown on the side of the second barrier layer 12 away from the potential well layer 13.

The epitaxial growth processes of the third isolation layer 16 and the fourth isolation layer 17 can refer to epitaxial growth processes of the first isolation layer 14 and the second isolation layer 15.

Although the present application is disclosed above, the present disclosure is not limited thereto. One of ordinary skill in the art can make various variants and modifications to the present disclosure without departing from the spirit and scope of the present disclosure. Therefore, the protection scope of the present disclosure should be set forth by the appended claims.

1-17. (canceled)

18. A resonant tunneling diode, comprising:
a first barrier layer;
a second barrier layer; and
a potential well layer between the first barrier layer and the second barrier layer,
wherein a material of the first barrier layer is AlₓIn_{y}N_{1-x-y}, 1>x>0, 1>y>0, a material of the second barrier layer is AlₘInₙN₁₋ₘ₋ₙ, 1>m>0, 1>n>0, and a material of the potential well layer comprises a gallium element.

19. The resonant tunneling diode of claim 18, wherein the material of the potential well layer comprises at least one of InGaN, GaN, or AlInGaN.

20. The resonant tunneling diode of claim 19, wherein the material of the first barrier layer is AlₓIn_{y}N_{1-x-y}, y≤45%; and the material of the second barrier layer is AlₘInₙN₁₋ₘ₋ₙ, n≤45%.

21. The resonant tunneling diode of claim 19, wherein the material of the first barrier layer is AlₓIn_{y}N_{1-x-y}, y≤30%; the material of the second barrier layer is AlₘInₙN₁₋ₘ₋ₙ, n≤30%.

22. The resonant tunneling diode of claim 18, wherein a first isolation layer is disposed between the first barrier layer and the potential well layer.

23. The resonant tunneling diode of claim 22, wherein a material of the first isolation layer comprises AlN.

24. The resonant tunneling diode of claim 18, further comprising:
a collector electrode,
an emitter electrode, the collector electrode close to the first barrier layer, the emitter electrode close to the second barrier layer; and
a third isolation layer between the collector electrode and the first barrier layer.

25. The resonant tunneling diode of claim 24, wherein a material of the collector electrode and a material of the emitter electrode comprise a GaN-based material.

26. The resonant tunneling diode of claim 24, wherein a material of the third isolation layer comprises AlN.

27. The resonant tunneling diode of claim 18, wherein
a second isolation layer is disposed between the second barrier layer and the potential well layer.

28. The resonant tunneling diode of claim 27, wherein
a material of the second isolation layer comprises AlN.

29. The resonant tunneling diode of claim 18, further comprising:
a collector electrode,
an emitter electrode, the collector electrode close to the first barrier layer, the emitter electrode close to the second barrier layer; and
a fourth isolation layer between the emitter electrode and the second barrier layer.

30. The resonant tunneling diode of claim 29, wherein
a material of the fourth isolation layer comprises AlN.

31. A method of manufacturing a resonant tunneling diode, comprising:
preparing a first barrier layer, a potential well layer, and a second barrier layer in sequence;
wherein a material of the first barrier layer is AlₓIn_{y}N_{1-x-y}, 1>x>0, 1>y>0, a material of the second barrier layer is AlₘInₙN₁₋ₘ₋ₙ, 1>m>0, 1>n>0, and a material of the potential well layer comprises a gallium element.

32. The method of manufacturing the resonant tunneling diode of claim 31, wherein the material of the potential well layer comprises at least one of InGaN, GaN, or AlInGaN.

33. The method of manufacturing the resonant tunneling diode of claim 32, wherein the material of the first barrier layer is AlₓIn_{y}N_{1-x-y}, y≤30%; and the material of the second barrier layer is AlₘInₙN₁₋ₘ₋ₙ, n≤30%.

34. The method of manufacturing the resonant tunneling diode of claim 31, wherein
in response to determining that the material of the first barrier layer is AlₓIn_{y}N_{1-x-y}, a temperature of preparing the first barrier layer ranges from 600° C. to 900° C.; and
in response to determining that the material of the second barrier layer is AlₘInₙN₁₋ₘ₋ₙ, a temperature of preparing the second barrier layer ranges from 600° C. to 900° C.

35. The method of manufacturing the resonant tunneling diode of claim 31, further comprising:
before preparing the potential well layer, preparing a first isolation layer on the first barrier layer; and
before preparing the second barrier layer, preparing a second isolation layer on the potential well layer.

36. The method of manufacturing the resonant tunneling diode of claim 31, further comprising:
preparing a collector electrode on a side of the first barrier layer away from the potential well layer; and
preparing an emitter electrode on a side of the second barrier layer away from the potential well layer.

37. The method of manufacturing the resonant tunneling diode of claim 36, further comprising:
before preparing the collector electrode on the side of the first barrier layer away from the potential well layer, preparing a third isolation layer on the side of the first barrier layer away from the potential well layer; and
before preparing the emitter electrode on the side of the second barrier layer away from the potential well layer, preparing a fourth isolation layer on the side of the second barrier layer away from the potential well layer.
